(19) United States
(12) Patent Application Publication
(10) Pub. No.: US 2013/0320387 A1
(43) Pub. Date: Dec. 5, 2013

(54) LIGHT EMITTING DIODE AND MANUFACTURING METHOD THEREOF

(71) Applicant: Shieh-Yang Sun, Taoyuan (TW)

(72) Inventor: Shieh-Yang Sun, Taoyuan (TW)

(73) Assignee: WALSIN LIHWA CORPORATION, Taoyuan (TW)

(21) Appl. No.: 13/750,070

(22) Filed: Jan. 25, 2013

(30) Foreign Application Priority Data
Jun. 5, 2012 (TW) 101120184

(51) Int. Cl. H01L 33/40; H01L 33/52

(52) U.S. Cl. CPC H01L 33/40; H01L 33/52
USPC 257/99; 438/26

(57) ABSTRACT

A light emitting diode (LED) and a manufacturing method thereof are provided. The LED comprises a semiconductor composite layer and an electrode. The semiconductor composite layer provides holes and electrons and allows the holes and the electrons to be combined to emit light. The electrode is formed on the semiconductor composite layer, wherein the electrode contains 30%˜98% of aluminum.

This application claims the benefit of Taiwan application Serial No. 101120184, filed Jun. 5, 2012, the subject matter of which is incorporated herein by reference.

### BACKGROUND OF THE INVENTION

1. Field of the Invention

The invention relates in general to a light emitting diode (LED) and a manufacturing method thereof, and more particularly to an LED whose electrode has high content of aluminum and a manufacturing method thereof.

2. Description of the Related Art

Along with the advance in technology, various lighting technologies are invented. Light emitting diode (LED) marks a significant milestone in the development of lighting technology. LED, having many advantages such as high efficiency, long lifespan and robustness, has been widely used in various electronic devices and lamps.

Conventional LED comprises a P-type semiconductor, an N-type semiconductor, and two electrodes formed on the P-type semiconductor and the N-type semiconductor respectively. To avoid the aluminum material of electrode being eroded by a chemical solution in the subsequent process, the content of aluminum in the electrode is less than 10%. However, the content of gold is increased due to the conductivity issue, and thereby the cost of conventional LED cannot be reduced effectively.

### SUMMARY OF THE INVENTION

The invention is directed to a light emitting diode (LED) and a manufacturing method thereof capable of reducing or avoiding the electrode of the LED being eroded.

According to one embodiment of the present invention, a light emitting diode (LED) is provided. The LED comprises a semiconductor composite layer and an electrode. The semiconductor composite layer provides holes and electrons and allows the holes and the electrons to be combined to emit light. The electrode is formed on the semiconductor composite layer, wherein the electrode contains 30%˜98% of aluminum.

According to another embodiment of the present invention, a manufacturing method of LED is provided. The method comprises the steps of: forming a semiconductor composite layer on a substrate; forming an electrode on the semiconductor composite layer; forming an encapsulating layer encapsulates the electrode, wherein the encapsulating layer is formed by a base metal.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 shows a cross-sectional view of an LED according to an embodiment of the invention;

FIG. 2 shows a cross-sectional view of an LED according to another embodiment of the invention; and

FIGS. 3A˜3C are manufacturing processes of an LED according to an embodiment of the invention.

### DETAILED DESCRIPTION OF THE INVENTION

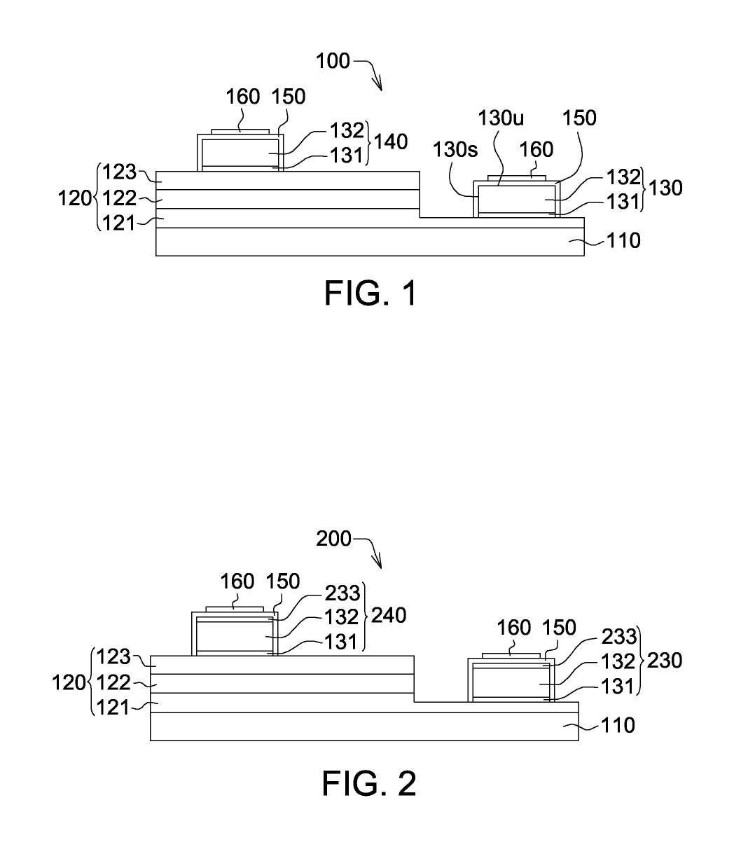

Referring to FIG. 1, a cross-sectional view of a light emitting diode (LED) 100 according to an embodiment of the invention is shown. The LED 100 comprises a substrate 110, a semiconductor composite layer 120, a first electrode 130, a second electrode 140, an encapsulating layer 150 and a pad layer 160.

The substrate 110 is realized by such as a silicon substrate, a gallium nitride substrate, a silicon carbide substrate, a sapphire substrate or one of the above substrates being processed, such as being patterned, but the invention is not limited thereto.

The semiconductor composite layer 120, disposed on the substrate 110, provides holes and electrons and allows the holes and the electrons to be combined to emit light. In greater details, the semiconductor composite layer 120, formed by multi semiconductor layers stacked together, comprises a first semiconductor 121, a light emitting layer 122, and a second semiconductor 123. The first semiconductor 121 is disposed on the substrate 110. The light emitting layer 122 is disposed on the first semiconductor 121 and exposes a portion of the first semiconductor 121. The second semiconductor 123 is disposed on the light emitting layer 122. The first semiconductor 121 is substantially parallel to the second semiconductor 123. The light emitting layer 122 is interposed between the first semiconductor 121 and the second semiconductor 123. Each of the first semiconductor 121, the light emitting layer 122 and the second semiconductor 123 can be realized by a single- or multi-layered structure according to actual needs.

The semiconductor composite layer 120 may be formed by ordinary semiconductor process, such as metal-organic chemical vapor deposition (MOCVD) epitaxy process, thin film deposition, lithography, etching process, or doping process. The first semiconductor 121 is realized by such as one of the P-type semiconductor and the N-type semiconductor, and the second semiconductor 123 is realized by the other one of the P-type semiconductor and the N-type semiconductor. The P-type semiconductor is realized by a nitrogen-based semiconductor doped with magnesium (Mg), boron (B), indium (In), gallium (Ga) or aluminum (Al). The N-type semiconductor is realized by a nitrogen-based semiconductor doped with silicon (Si), phosphorus (P), antimony (Ti), or arsenic (As). The light emitting layer 122 may be realized by a III-V binary compound semiconductor, a III-V multi-element compound semiconductor or a II-VI binary compound semiconductor. Examples of the III-V binary compound include gallium arsenide (GaAs), indium phosphide (InP), gallium phosphide (GaP), and gallium nitride (GaN). Examples of the III-V multi-element compound include aluminum gallium arsenide (AlGaAs), gallium arsenide phosphide (GaAsP), aluminum gallium indium phosphide (AlGaInP), and aluminum indium gallium arsenide (AlInGaAs). Examples of the II-VI binary compound include cadmium selenide (CdSe), cadmium sulfide (CdS), and zinc selenide (ZnSe).

The first electrode 130 is disposed on the exposed portion of the first semiconductor 121. The first electrode 130 is a single- or multi-layered structure formed by at least one of gold, aluminum, silver, copper, platinum, chromium, tin, nickel, titanium, chromium alloy, nickel alloy, copper-silicon alloy, aluminum-copper-silicon alloy, aluminum-silicon alloy, gold-tin alloy and a combination thereof, but the invention is not limited thereto. The first electrode 130 of the present embodiment is exemplified by a double-layered structure, and comprises a first layer structure 131 and a second layer structure 132.

The first layer structure 131, disposed on the first semiconductor 121, is formed by a material selected from a group consisting of chromium, chromium alloy, nickel, nickel alloy, tin, titanium or a combination thereof. These materials have strong viscosity which enhances the associativity between the first electrode 130 and the semiconductor composite layer 120.

The second layer structure 132, disposed on the first layer structure 131, is formed by a material selected from a group consisting of gold, aluminum, silver, copper, platinum, copper-silicon alloy, aluminum-copper-silicon alloy, aluminum-silicon alloy, gold-tin alloy or a combination thereof. The second layer structure 132 is preferably formed by materials having superior conductivity such as aluminum, gold or a combination thereof, so that the overall conductivity of the first electrode 130 is increased and conformed to an expected level of the design.

The first electrode 130 may contain 30%˜98% of aluminum, and such aluminum content can be realized through the design in the layer thickness of the first electrode 130. For example, the first layer structure 131 is formed by chromium and has a thickness of about 1000 angstroms, and the second layer structure 132 is formed by aluminum and has a thickness of about 33000 angstroms, so that the first electrode 130 may contain about 97% of aluminum. Due to the high content of aluminum, the content of gold, which is relatively expensive, can be reduced, and the cost of the first electrode 130 can thus be reduced accordingly.

The second electrode 140 is formed on the second semiconductor 123. The structure and material of the second electrode 140 are similar to that of the first electrode 130, and are not repeated here. Despite the quantity of electrode is exemplified by two (the first electrode 130 and the second electrode 140) in the embodiment of the invention, the invention is not limited thereto. For example, the quantity of electrode can be one or more than two.

The encapsulating layer 150 encapsulates the first electrode 130 and the second electrode 140. The encapsulating layer 150 is formed by a base metal, such as chromium, chromium alloy, nickel, tin, titanium, nickel alloy or a combination thereof. Since the encapsulating layer 150 is formed by a material selected from base metals, the cost of the LED 100 can thus be greatly reduced. In another embodiment, the encapsulating layer 150 can be formed by an anti-oxidation and/or anti-erosion material. In addition, the thickness of the encapsulating layer 150 is between 300˜500 angstroms.

The encapsulating layer 150 encapsulates the entire upper surface 130u and the entire lateral surface 130s of the first electrode 130 to avoid the aluminum material of the first electrode 130 being exposed and eroded in the subsequent processing environment or atmospheric environment. Similarly, the second electrode 140 may also be encapsulated by the encapsulating layer 150, and the similarities are not repeated here.

The pad layer 160 is formed on the encapsulating layer 150 and can be used as a supporting pad of the metal wire (not illustrated). The pad layer 160 is formed by such as gold (Au) or a gold-containing alloy. Since the electrode contains a certain percentage of aluminum having superior conductivity, the usage amount of the pad layer 160 can be reduced. For example, the thickness of the pad layer 160 is only 500 angstroms or even thinner, so that the cost of the LED 100 can be greatly reduced.

Since the first electrode 130 and the second electrode 140 are protected by the encapsulating layer 150, the electrodes being exposed in the subsequent processing environment, packaging environment or atmospheric environment will not be eroded and peeled off. Consequently, the metal wire soldered on the pad layer 160 is firmly fixed on electrode and will not be peeled off together with other electrodes.

In another embodiment, the LED 100 further comprises a transparent conductive layer (not illustrated) formed on the second semiconductor 123. The transparent conductive layer is formed by a transparent material, such as indium tin oxide (ITO) or indium zinc oxide (IZO). The current spreading effect of the transparent conductive layer allows the current to uniformly flow to the light emitting layer 122 from the second semiconductor 123. The thickness of the transparent conductive layer is about 2800 angstroms.

Referring to FIG. 2, a cross-sectional view of an LED 200 according to another embodiment of the invention is shown. The LED 200 comprises a substrate 110, a semiconductor composite layer 120, a first electrode 230, a second electrode 240 and an encapsulating layer 150. The components similar to the above embodiment retain the same numeric designation, and the materials, structures and selection conditions are identical to the above embodiment and are not repeated here.

Each of the first electrode 230 and the second electrode 240 is exemplified by a three-layered structure comprising a first layer structure 131, a second layer structure 132 and a third layer structure 233. The first layer structure 131 of the first electrode 230 and that of the second electrode 240 are formed on the first semiconductor 121 and the second semiconductor 123 respectively. The second layer structure 132 is formed on the first layer structure. The third layer structure 233 is formed on the second layer structure 132. The third layer structure 233 has a thickness of 200 angstroms, and may be formed by a material selected from chromium, chromium alloy, tin, titanium, nickel, nickel alloy or a combination thereof. Moreover, the third layer structure 233 and the first layer structure 131 may be formed by the same or different materials.

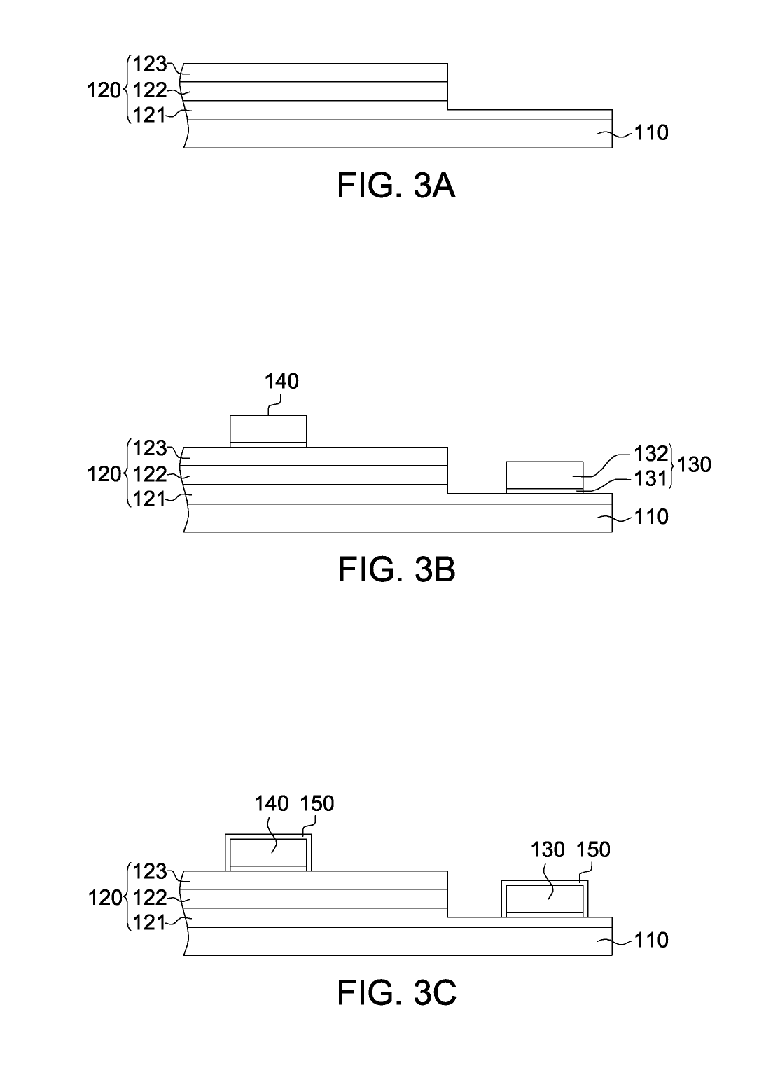

Referring to FIGS. 3A˜3C, manufacturing processes of an LED according to an embodiment of the invention are shown. The components similar to the above embodiment retain the same numeric designation, and the materials, structures and selection conditions are identical to the above embodiment and are not repeated here.

As indicated in FIG. 3A, a semiconductor composite layer 120 may be formed on the substrate 110 by the metal-organic chemical vapor deposition (MOCVD) epitaxy process, wherein the semiconductor composite layer 120 comprises a first semiconductor 121, a light emitting layer 122 and a second semiconductor 123. In greater details, the first semiconductor 121, the light emitting layer 122 and the second semiconductor 123 are sequentially formed on the substrate 110.

Next, a photo-resist opening (not illustrated) is defined by exposure and development processes. Then, inductively coupled plasma (ICP) is used to etch the second semiconductor 123 disposed in the photo-resist opening, and continues to etch the light emitting layer 122 and the first semiconductor 121 downwardly until a portion of the first semiconductor 121 is exposed.

Referring to FIG. 3B, a first electrode 130 is formed on the exposed portion of the first semiconductor 121 by such as vapor deposition process, sputtering process and lithography process, and a second electrode 140 is then formed on the second semiconductor 123. In greater details, a photo-resist opening (not illustrated) is defined in the exposed portion of the first semiconductor 121 and the exposed portion of the second semiconductor 123 respectively by exposure and development processes. Then, the first layer structure 131 and the second layer structure 132 are sequentially formed in the photo-resist openings by vapor deposition to form the first electrode 130 and the second electrode 140 respectively. In another embodiment, the first layer structure 131, the second layer structure 132 and the third layer structure 233 may be sequentially formed in the photo-resist openings to form the first electrode 230 (FIG. 2) and the second electrode 240 (FIG. 2) respectively.

As indicated in FIG. 3C, an encapsulating layer 150 encapsulating the first electrode 130 and the second electrode 140 may be formed by such as vapor deposition process, sputtering process and lithography process, wherein the encapsulating layer 150 is formed by a base metal such as chromium, chromium alloy, tin, titanium, nickel, nickel alloy or a combination thereof.

Then, a pad layer 160 shown in FIG. 1 may be formed on the encapsulating layer 150 by such as vapor deposition process, sputtering process and lithography process. Thus, the LED 100 as illustrated in FIG. 1 is completed.

The manufacturing method of the LED 200 shown in FIG. 2 is similar to that of the LED 100, and the similarities are not repeated here.

The LED and the manufacturing method thereof disclosed in the above embodiments according to the invention have many advantages exemplified below:

(1). In an embodiment, the electrode contains 30%˜98% of aluminum, so that the content of gold, which is relatively expensive, can be reduced and the cost of electrode is reduced accordingly.

(2). In an embodiment, the encapsulating layer, which completely encapsulates the electrode, is formed by a base metal, so that the cost of LED is greatly reduced.

(3). In an embodiment, the encapsulating layer encapsulates the entire electrode to avoid the electrode being exposed and becoming oxidized and eroded in the subsequent processing environment.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A light emitting diode (LED), comprising:
a semiconductor composite layer used for providing holes and electrons and allowing the holes and the electrons to be combined to emit light; and
an electrode formed on the semiconductor composite layer, wherein the electrode contains 30%˜98% of aluminum.

2. The LED according to claim 1, wherein the electrode is a single- or multi-layered structure formed by at least one of gold, aluminum, silver, copper, platinum, chromium, tin, nickel, titanium, chromium alloy, nickel alloy, copper-silicon alloy, aluminum-copper-silicon alloy, aluminum-silicon alloy, gold-tin alloy and a combination thereof.

3. The LED according to claim 1, further comprising:
an encapsulating layer encapsulating the electrode and formed by a base metal.

4. The LED according to claim 3, wherein the base metal is chromium, chromium alloy, nickel, tin, titanium, nickel alloy or a combination thereof.

5. An LED, comprising:
a semiconductor composite layer used for providing holes and electrons and allowing the holes and the electrons to be combined to emit light;
an electrode formed on the semiconductor composite layer; and
an encapsulating layer encapsulating the electrode and formed by a base metal.

6. The LED according to claim 5, wherein the electrode is a single- or multi-layered structure formed by at least one of gold, aluminum, silver, copper, platinum, chromium, tin, nickel, titanium, chromium alloy, nickel alloy, copper-silicon alloy, aluminum-copper-silicon alloy, aluminum-silicon alloy, gold-tin alloy and a combination thereof.

7. The LED according to claim 5, wherein the electrode contains 30%˜98% of aluminum.

8. The LED according to claim 5, wherein a base metal is chromium, chromium alloy, nickel, tin, titanium, nickel alloy or a combination thereof.

9. A manufacturing method of LED, comprising:
forming a semiconductor composite layer on a substrate;
forming an electrode on the semiconductor composite layer; and
forming an encapsulating layer encapsulating the electrode, wherein the encapsulating layer is formed by a base metal.

10. The manufacturing method according to claim 9, wherein the electrode is a single- or multi-layered structure formed by at least one of gold, aluminum, silver, copper, platinum, chromium, tin, nickel, titanium, chromium alloy, nickel alloy, copper-silicon alloy, aluminum-copper-silicon alloy, aluminum-silicon alloy, gold-tin alloy and a combination thereof.

11. The manufacturing method according to claim 9, wherein the electrode contains 30%˜98% of aluminum.

12. The manufacturing method according to claim 9, wherein the base metal is chromium, chromium alloy, nickel, tin, titanium, nickel alloy or a combination thereof.
